(19) United States
(12) Patent Application Publication
(10) Pub. No.: US 2007/0015348 A1
(43) Pub. Date: Jan. 18, 2007

(54) Crosspoint resistor memory device with back-to-back Schottky diodes

(75) Inventors: Sheng Teng Hsu, Camas, WA (US); Tingkai Li, Vancouver, WA (US)

Correspondence Address: SHARP LABORATORIES OF AMERICA, INC.;C/O LAW OFFICE OF GERALD MALISZEWSKI, P.O. BOX 270829, SAN DIEGO, CA, 92198-2829, US

(73) Assignee: Sharp Laboratories of America, Inc.

(21) Appl. No.: 11/295,778

(22) Filed: Dec. 7, 2005

Related U.S. Application Data
(63) Continuation-in-part of application No. 11/184,660, filed on Jul. 18, 2005.
(63) Continuation-in-part of application No. 11/216,398, filed on Aug. 31, 2005.

(51) Int. Cl. H01L 21/28; H01L 21/44

(52) U.S. Cl. 438/570

(57) ABSTRACT

A metal/semiconductor/metal (MSM) back-to-back Schottky diode, a resistance memory device using the MSM diode, and associated fabrication processes are provided. The method includes: providing a substrate; forming a metal bottom electrode overlying the substrate, having a first work function; forming a semiconductor layer overlying the metal bottom electrode, having a second work function, less than the first work function; and, forming a metal top electrode overlying the semiconductor layer, having a third work function, greater than the second work function. The metal top and bottom electrodes can be materials such as Pt, Au, Ag, TiN, Ta, Ru, or TaN. In one aspect, the metal top electrode and metal bottom electrode are made from the same material and, therefore, have identical work functions. The semiconductor layer can be a material such as amorphous silicon (a:Si), polycrystalline Si, InOx, or ZnO.

### RELATED APPLICATIONS

This application is a Continuation-in-Part of a pending patent application entitled, MSM BINARY SWITCH MEMORY DEVICE, invented by Sheng Teng Hsu et al., Ser. No. 11/184,660, filed Jul. 18, 2005.

This application is a Continuation-in-Part of a pending patent application entitled, METAL/ZnOx/METAL CURRENT LIMITER, invented by Tingkai Li et al., Ser. No. 11/216,398, filed Aug. 31, 2005.

The above-mentioned applications are both expressly incorporated herein by reference, and both claim priority under 35 U.S.C. §120.

### BACKGROUND OF THE INVENTION

1. Field of the Invention

This invention generally relates to an integrated circuit (IC) fabrication process and, more particularly, to a crosspoint resistor memory with an MSM device that acts as a back-to-back Schottky diode.

2. Description of the Related Art

A cross-point memory array is a matrix of memory elements, with electrical contacts arranged along x-axes (i.e., word lines) and along y-axes (i.e., bit lines). In some aspects, a digital value is stored as a memory resistance (high or low). The memory state of a memory cell can be read by supplying a voltage to the word line connected to the selected memory element. The resistance or memory state can be read as an output voltage of the bit line connected to the selected memory cell.

Cross-point resistor memory arrays are prone to read disturbance problems. As part of the read operation, electric current flows from a selected word line, through a selected memory cell, to a bit line. However, current also flows into unselected word lines that happen to cross over the selected bit line. The conduction of current into unselected word lines acts to decrease the output impedance and, hence, reduce the output voltage. To clearly distinguish memory states, the output voltage must be clearly distinguishable.

The undesired flow of current through a resistance memory cell can be addressed through the use of series-connected diodes, since reverse biased diodes are poor conductors. However, this same feature makes a one-diode/one resistor (1D1R) memory difficult to program. Programming voltages cannot be used that reverse bias the diode. Therefore, 1D1R cells are better for suited for unipolar programming. Further, diodes are preferable formed from single crystal silicon, for optimal performance. However, large crystal grains are difficult to form using thin-film deposition processes.

Many cross-point resistor memory array structures have been proposed in attempts to minimize cross-talk problems during read operations in a large area cross-point resistor memory array. IRID memory cell are well suited for a mono-polarity programming memory array. However, good diodes can only be fabricated on single crystal silicon. For multi-layer three-dimensional arrays, the upper layer of a diode is formed by re-crystallization of deposited silicon, and the resulting diode usually exhibits poor electrical properties. In addition, the diode must be formed from a silicon film that is fairly thick.

Rinerson et al., U.S. Pat. No. 6,753,561, have proposed a memory cell of a metal/insulator/metal (MIM) structure in series with a resistor memory. The MIM device is non-conductive at low biases. When the bias voltage is higher than a certain value, the conductivity drastically increases. This voltage is called either the “current rise-up voltage” or “varistor voltage”. The high field generated in response to the MIM high current region is associated with impact ionization. MIM devices are well known to be unstable if subjected to high current density stress. This is due to deep trap states in the insulator and the local avalanche breakdown when a high electric field is applied to the insulator. As a result, the current voltage characteristics are reversible only at relatively low current conditions. Therefore, MIM non-ohmic devices are not suitable for cross-point memory cells, which require a large numbers of programming operations. In addition, Rinerson does not teach specific MIM materials, or how a MIM device is fabricated.

### SUMMARY OF THE INVENTION

Described herein is a back-to-back diode device that permits current flow in both forward and reverse directions under higher voltage (forward and reverse) bias conditions, but blocks current in under lower voltage bias conditions. The current limiter can be added to a resistance memory cell, to permit high voltage bipolar programming, without the penalty of flowing current into unselected word lines during lower voltage read operations.

Many conventional cross-point resistor memory arrays suffer from read disturbance problems, as electric current flows from a selected word line, through a selected memory cell to a bit line, and then into unselected word lines which cross over the bit line. A cross-point array made with a current limiter in the memory cells minimizes the current flow into the unselected word lines, maximizing the output (read) voltage.

A metal/semiconductor/metal (MSM) back-to-back Schottky barrier device exhibits a symmetrical non-ohmic property with respect to both positive and negative bias voltages. This device can be used as memory cell current limiter to resistor cross-point memory array. Since the conductivity of the semiconductor is high, and the capture cross-section of trap state is small, the device is stable operating at high fields. The current density of MSM device can be several orders of magnitude higher than that of MIM devices.

Accordingly, a method is provided for forming a MSM back-to-back Schottky diode. The method comprises: providing a substrate; forming a metal bottom electrode overlying the substrate, having a first work function; forming a semiconductor layer overlying the metal bottom electrode, having a second work function, less than the first work function; and, forming a metal top electrode overlying the semiconductor layer, having a third work function, greater than the second work function.

The metal top and bottom electrodes can be materials such as Pt, Au, Ag, Ru, TiN, Ta, or TaN. In one aspect, the metal top electrode and metal bottom electrode are made from the same material and, therefore, have identical work functions. The semiconductor layer can be a material such as amorphous silicon (a:Si), polycrystalline Si, InOx, or ZnO. The semiconductor layer may be deposited using a process such as atomic layer deposition (ALD), chemical vapor deposition (CVD), physical vapor deposition (PVD), spin-coating, direct current (DC) sputtering, radio frequency (RF) sputtering, or metalorganic chemical vapor deposition (MOCVD).

A method is also provided for forming a resistance memory device with a MSM back-to-back Schottky diode. The method comprises: forming a memory resistor bottom electrode; forming a memory resistor material overlying the memory resistor bottom electrode; forming a MSM metal bottom electrode overlying the memory resistor material, having a first work function; forming a MSM semiconductor layer overlying the metal bottom electrode, having a second work function, less than the first work function; and, forming a MSM metal top electrode overlying the semiconductor layer, having a third work function, greater than the second work function.

Additional details of the above-described methods, a MSM back-to-back Schottky diode, and a resistance memory device with a MSM back-to-back Schottky diode are provided below.

### BRIEF DESCRIPTION OF THE DRAWINGS

FIG. 1 is a partial cross-sectional view of a metal/semiconductor/metal (MSM) back-to-back Schottky diode.

FIG. 2 is a partial cross-sectional view of a resistance memory device with a MSM back-to-back Schottky diode.

FIG. 3 is a partial cross-sectional view of a variation of the memory device of FIG. 2.

FIG. 4 is a partial cross-sectional view of an exemplary unit memory cell from a cross-point resistor memory array.

FIG. 5 is a graph depicting the ideal IV (current/voltage) characteristics of a MSM back-to-back Schottky diode device.

FIG. 6 is a graph depicting the electrical properties of a Metal/Al₂O₃/Metal diode.

FIGS. 7 and 8 depict the electrical properties of amorphous silicon (a:Si) and zinc oxide (ZnO) MSM devices, respectively.

FIG. 9 is a flowchart illustrating a method for forming a metal/semiconductor/metal (MSM) back-to-back Schottky diode.

FIG. 10 is a flowchart illustrating a method for forming a resistance memory device with a MSM back-to-back Schottky diode.

### DETAILED DESCRIPTION

FIG. 1 is a partial cross-sectional view of a metal/semiconductor/metal (MSM) back-to-back Schottky diode. The MSM diode 100 comprises a substrate 102 and a metal bottom electrode (MBE) 104 overlying the substrate 102. The substrate 102 is not limited to any particular material, and may be a material such as Si, Ge, SiO₂, GeAs, glass, quartz, or plastic. The metal bottom electrode 104 has a first work function. A semiconductor layer (S) 106 overlies the metal bottom electrode 104, and has a second work function that is less than the first work function. A metal top electrode 108 overlies the semiconductor layer 106, and has a third work function, greater than the second work function.

Work function is a measue of the minimum energy, as expressed in electron volts (eV), needed to remove an electron from the Fermi level in a metal, to a far point. Typically, a metal's work function is approximately half the ionization energy of a free atom of the metal. Work function is an important consideration is the design of Schottky diodes, which have a metal/semiconductor interface. Work function is closely related to the threshold voltage of a MOSFET device, which typically uses a metal gate electrode overlying a semiconductor channel region.

The metal top electrode 108 and metal bottom electrode 104 may be materials such as Pt, Au, Ag, Ru, TiN, Ta, or TaN. However, other materials are well known in the art that may be used as a conductive electrode. In one aspect, the metal top electrode 108 and metal bottom electrode 104 are the same material and, therefore, have identical work functions. The semiconductor layer 106 may be a material such as amorphous silicon (a:Si), polycrystalline Si, InOx, or ZnO. Once again, however, the device 100 is not necessarily limited to just this list of materials.

In one aspect, the semiconductor layer 106 has a thickness 110 in the range of about 10 nanometers (nm) to 100 nm. The metal top electrode 108 and metal bottom electrode 104 each have a thickness 112 in the range of about 30 to 200 nm. Note, the metal top electrode 108 need not necessarily be the same thickness as the metal bottom electrode 104. In another aspect, the semiconductor layer 106 includes an n-type or a p-type dopant.

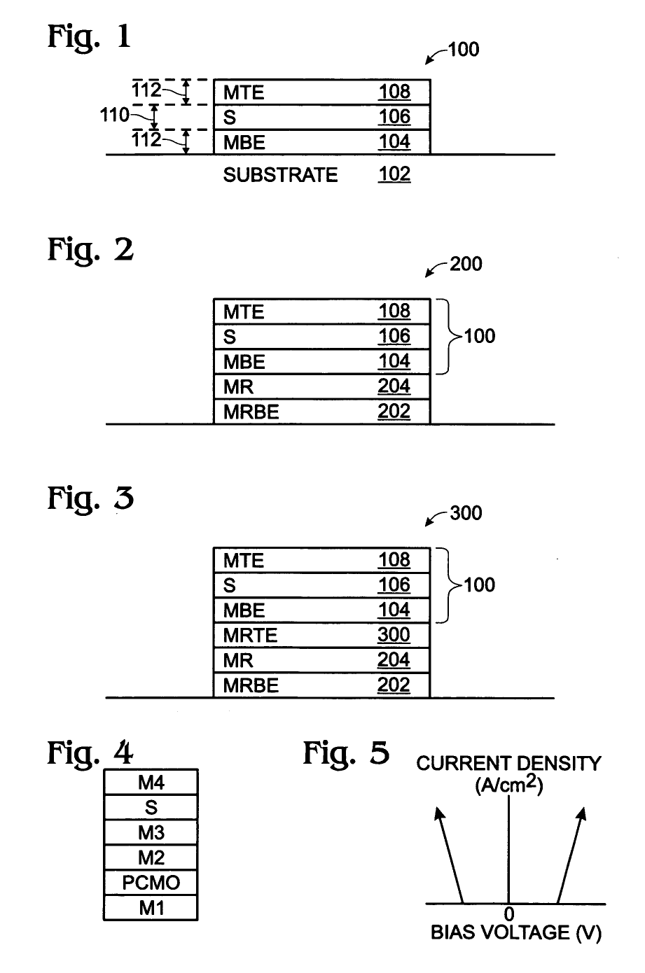

FIG. 2 is a partial cross-sectional view of a resistance memory device with a MSM back-to-back Schottky diode. The device 200 comprises a memory resistor bottom electrode (MRBE) 202 and a memory resistor (MR) material 204 overlying the memory resistor bottom electrode 202. A MSM diode 100 overlies the memory resistor material. As described in FIG. 1, the MSM diode 100 includes a MSM metal bottom electrode 104 overlying the memory resistor material 204, having a first work function. A MSM semiconductor layer 106 overlies the metal bottom electrode 104, and has a second work function, less than the first work function. A MSM metal top electrode 108 overlies the semiconductor layer 106, and has a third work function, greater than the second work function. Details of the MSM diode 100 have been presented above in the description of FIG. 1, and will not be repeated here in the interest of brevity.

FIG. 3 is a partial cross-sectional view of a variation of the memory device of FIG. 2. This variation of the memory device includes all the elements of the device shown in FIG. 2, and further comprises a memory resistor top electrode (MRTE) 300 interposed between the memory resistor material 204 and the MSM metal bottom electrode 104.

Referencing either FIG. 2 or 3, the memory resistor material 204 overlying the memory resistor bottom electrode 202 may be a material such as Pr_{0.3}Ca_{0.7}MnO₃ (PCMO), colossal magnetoresistive (CMR) film, transition metal oxides, Mott insulators, high-temperature super conductor (HTSC), or perovskite materials.

The MSM top metal electrode 108 may be a word line in an array of connected memory devices. In a memory array, a plurality of devices 200 would be attached to each bit line and word line, as is well understood in the art. Then, the MR bottom electrode 202 would be a bit line connected to other memory devices (not shown) in the array. In other aspects not shown, the MSM diode 100 is formed “under” the MR cell, as opposed to “over” the memory cell as shown. That is, the MSM bottom metal electrode 104 would be the bit line, with the memory resistor bottom electrode 202 formed overlying the MSM top electrode 108. Then, the MR top electrode 300 would be a word line. Materials such as Pt, Ir, Au, Ag, Ru, TiN, Ti, Al, ALCu, Pd, Rh, W, Cr, conductive oxides, Ag, Au, Pt, Ir, or TiN, may potentially be used as the MR top and bottom electrodes.

### Functional Description

A crosspoint resistor memory array requires a current limiting device, such as diode, in series with the bit memory resistor, to minimize the programming interference, programming disturbance, and read disturbances. A crosspoint memory array with a diode in series with the memory resistance bit cells can only be programmed using mono-polarity voltage pulses. Since a good diode cannot be fabricated onto metal multi-layers, the integration of a resistor cross-point memory array with a diode/resistor cell is not feasible. A MIM current limiter cannot be used in place of diode, as a metal-insulator-metal device is not reliable, even in a very small current density operation. The reliability problems are due to the deep trap states in the insulator and the local catastrophic breakdown in the insulator. However, if the insulator is replaced with a semiconductor material, a back-to-back Schottky structure can be formed.

FIG. 4 is a partial cross-sectional view of an exemplary unit memory cell from a cross-point resistor memory array. PCMO is used as the memory resistor. In one aspect, the top electrode and the bottom electrodes of the memory resistor, M1 and M2, are made with noble metals or metal compounds, such as Pt, Au, Ag, TiN, Ta, Ru, TaN, and similar materials. The work function of the MSM diode electrodes, M3 and M4, is larger than the work function of the semiconductor, S, of the MSM device. In one aspect, it is preferable that the same material be used for both M3 and M4, so that the MSM device has symmetrical properties with respect to the origin of the bias voltage. The M3 layer may not be necessary if M2 is also suitable for MSM fabrication. Some materials suitable for M3 and M4 are Pt, TiN, Ag, Au, Ta, Ti, Ru, and TaN.

FIG. 5 is a graph depicting the ideal IV (current/voltage) characteristics of a MSM back-to-back Schottky diode device.

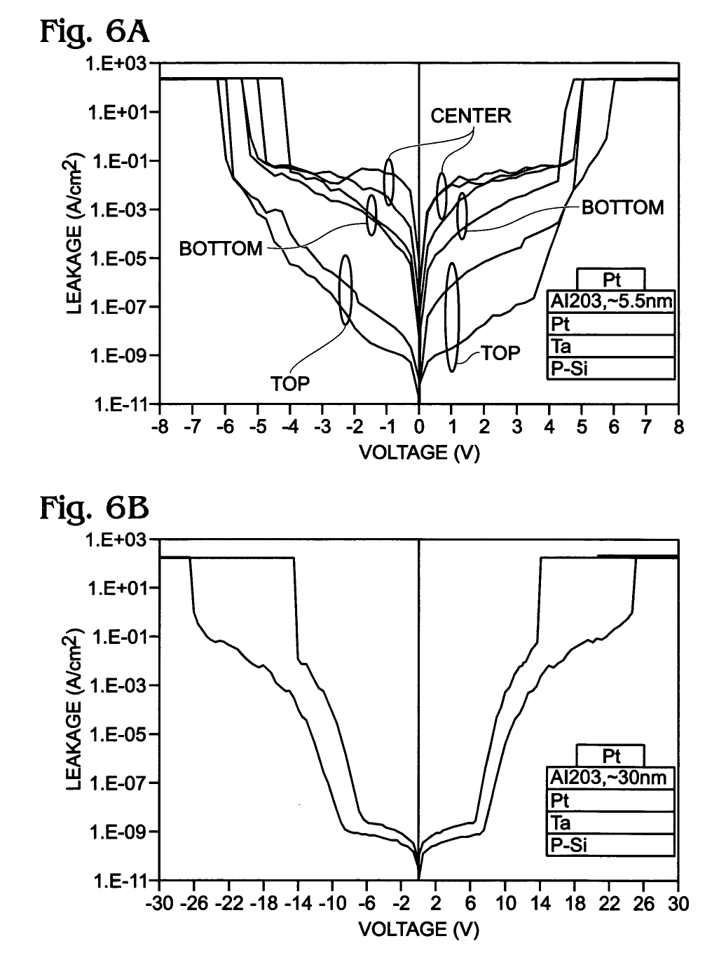

FIGS. 6A and 6B are graphs depicting the electrical properties of a Metal/Al₂O₃/Metal diode. Atomic layer deposition (ALD) processes can be used to deposit the Al₂O₃ thin film. The thicknesses of the Al₂O₃ for FIGS. 6A and 6B are 5.5 nm and 30 nm, respectively. As shown in both figures, the breakdown current is practically independent of the thickness of the insulator. The maximum current density is about 0.1 A/cm², which is too small for some crosspoint resistor memory array applications. In addition, at that current level, the insulator is very unstable.

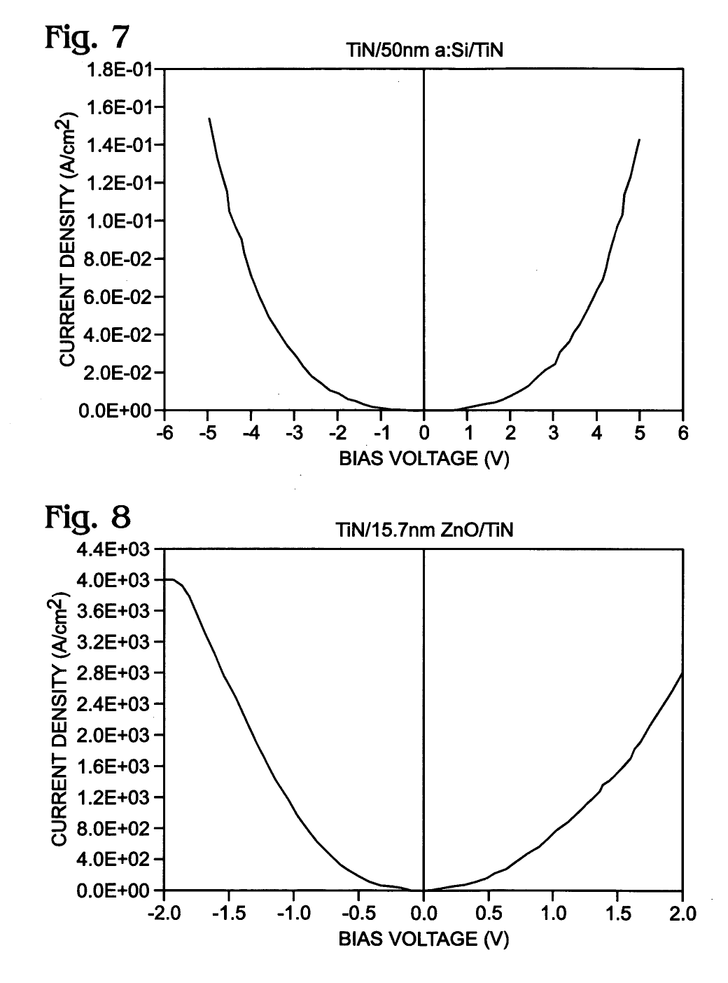

FIGS. 7 and 8 depict the electrical properties of amorphous silicon (a:Si) and zinc oxide (ZnO) MSM devices, respectively. TiN is used as the metal in both the a:Si and ZnO MSM devices. Both the a:Si and ZnO MSM devices reliably handle high current densities. The maximum current density of the MSM device depends upon the thickness of the semiconductor. It is possible to obtain reliable devices with current densities higher than 1000 A/cm². Although only a:Si and ZnO MSM data is specifically shown, any semiconductive material can be used for this application as long as the work function of the semiconductor is lower than that of the metal electrodes.

The MSM device functions as a back-to-back Schottky diode. The current density is dependent upon the barrier height of the metal, with respect to the semiconductor. The series resistance of the MSM device may be decreased, by reducing the thickness and the resistivity of the semiconductor material. If the semiconductor is too thin, the leakage current of the device increases and the low bias voltage current may be too large for some practical memory cell applications. Since the purpose of MSM device is to limit the current flow through the unselected cells in an array, the IV properties of the MSM device do not have to be symmetric around the zero bias voltage. Therefore, the MSM electrodes need not be the same material.

The fabrication process is as follows:

1. After completing silicon-integrated supporting circuitry, deposit an interlayer silicon oxide. The surface of the silicon wafer is planarized. A contact via is etched and filled with a suitable material, such as W, WSi₂, TiN, or n+ doped polysilicon.

2. Deposit a bottom electrode metal M1, PCMO, top electrode metal M2, and electrode M3.

3. The semiconductor is then deposited using any suitable state-of-the-art process such as physical vapor deposition (PVD), chemical vapor deposition (CVD), or metalorganic deposition (MOD). The semiconductor may be doped or undoped. The thickness of the semiconductor layer is from about 10 nm to 100 nm.

4. Deposit metal M4 and a hard mask.

5. Plasma etch M4, S, M3, M2, PCMO, and M1 to form a memory resistor in series with the MSM device, in a single stack. The memory cell stack may also be etched using multiple masks and etchings to simplify the etching process.

6. Deposit a protection insulation layer, such as Al₂O₃ or Si₃N₄.

7. Deposit passivation oxide.

8. Complete interconnect metallization using any state-of-the-art process.

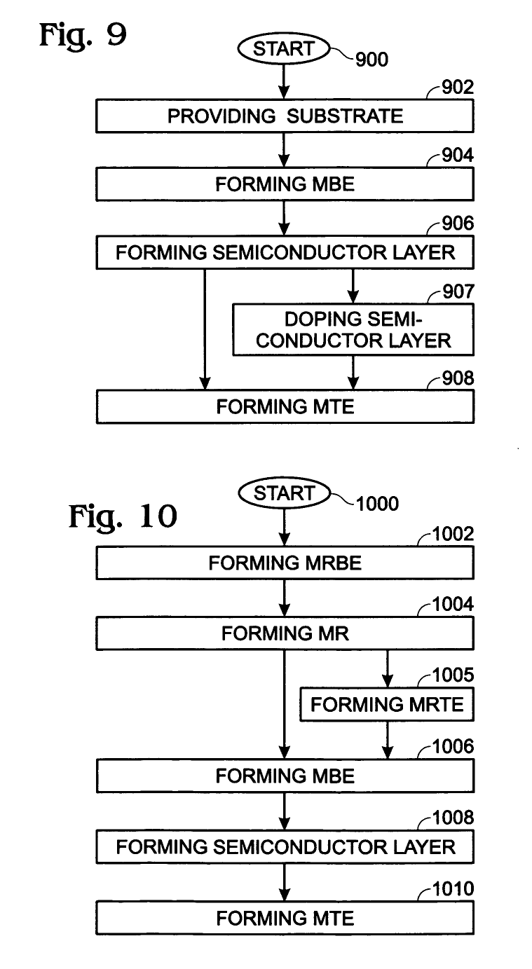

FIG. 9 is a flowchart illustrating a method for forming a metal/semiconductor/metal (MSM) back-to-back Schottky diode. Although the method is depicted as a sequence of numbered steps for clarity, the numbering does not necessarily dictate the order of the steps. It should be understood that some of these steps may be skipped, performed in parallel, or performed without the requirement of maintaining a strict order of sequence. The method starts at Step 900.

Step 902 provides a substrate. Step 904 forms a metal bottom electrode (MBE) overlying the substrate, having a first work function. Step 906 forms a semiconductor layer overlying the metal bottom electrode, having a second work function, less than the first work function. In one aspect an additional step, Step 907, dopes the semiconductor layer with either an n-type or a p-type dopant. Step 908 forms a metal top electrode (MTE) overlying the semiconductor layer, having a third work function, greater than the second work function.

In one aspect, forming the metal top electrode (Step 908) and metal bottom electrode (Step 904) includes forming the metal electrodes from materials such as Pt, Au, Ag, TiN, Ta, Ru, or TaN, to name a few examples. In another aspect, Steps 904 and 908 form the metal bottom and top electrodes, respectively, from the same material. Therefore, the top and bottom electrodes have identical work functions.

In a different aspect, forming the semiconductor layer in Step 906 includes forming the semiconductor layer from a material such as a:Si, polycrystalline Si, InOx, or ZnO. Step 906 may deposit the semiconductor material using a process such as atomic layer deposition (ALD), chemical vapor deposition (CVD), physical vapor deposition (PVD), spin-coating, direct current (DC) sputtering, radio frequency (RF) sputtering, or metalorganic chemical vapor deposition (MOCVD).

In one aspect, forming the semiconductor layer in Step 906 includes depositing the semiconductor material to a thickness in the range of about 10 nm to 100 nm. Forming the metal top electrode in Step 908 and the metal bottom electrode in Step 904 includes forming each electrode with a thickness in the range of about 30 to 200 nm.

FIG. 10 is a flowchart illustrating a method for forming a resistance memory device with a MSM back-to-back Schottky diode. The method starts as Step 1000. Step 1002 forms a memory resistor bottom electrode (MRBE). Step 1004 forms a memory resistor (MR) material overlying the memory resistor bottom electrode. Step 1006 forms a MSM metal bottom electrode (MBE) overlying the memory resistor material, having a first work function. In one aspect, Step 1005 forms a memory resistor top electrode (MRTE) interposed between the memory resistor material and the MSM metal bottom electrode. Step 1008 forms a MSM semiconductor layer overlying the metal bottom electrode, having a second work function, less than the first work function. Step 1010 forms a MSM metal top electrode (MTE) overlying the semiconductor layer, having a third work function, greater than the second work function.

Forming the memory resistor material overlying the memory resistor bottom electrode in Step 1004 includes forming the memory resistor from a material such as PCMO, CMR film, transition metal oxides, Mott insulators, HTSC, or perovskite materials.

Details of fabricating the MSM diode are provided in the description of FIG. 9 and are not repeated here in the interest of brevity. Although the fabrication process specifically describes the formation of the MR device prior to (underlying) the MSM diode, in other aspects it would be possible to fabricate the MSM diode prior to (underlying) the MR device.

A MSM back-to-back Schottky diode, an MSM diode resistor memory device, and corresponding fabrication processes have been provided. Examples of process details have been presented to illustrate the invention. Likewise, a resistance memory device has been presented as an example of an application. However, the invention is not limited to merely these examples. Other variations and embodiments of the invention will occur to those skilled in the art.

We claim:

1. A method for forming a metal/semiconductor/metal (MSM) back-to-back Schottky diode, the method comprising:
providing a substrate;
forming a metal bottom electrode overlying the substrate, having a first work function;
forming a semiconductor layer overlying the metal bottom electrode, having a second work function, less than the first work function; and,
forming a metal top electrode overlying the semiconductor layer, having a third work function, greater than the second work function.

2. The method of claim 1 wherein forming the metal top electrode and metal bottom electrode includes forming the metal electrodes from the same material, having identical work functions.

3. The method of claim 1 wherein forming the metal top electrode and metal bottom electrode includes forming the metal electrodes from materials selected from the group consisting of Pt, Au, Ag, TiN, Ta, Ru, and TaN.

4. The method of claim 1 wherein forming the semiconductor layer includes forming the semiconductor layer from a material selected from the group consisting of amorphous silicon (a:Si), polycrystalline Si, InOx, and ZnO.

5. The method of claim 1 wherein forming the semiconductor layer includes depositing the semiconductor material using a process selected from the group consisting of atomic layer deposition (ALD), chemical vapor deposition (CVD), physical vapor deposition (PVD), spin-coating, direct current (DC) sputtering, radio frequency (RF) sputtering, and metalorganic chemical vapor deposition (MOCVD).

6. The method of claim 1 wherein forming the semiconductor layer includes depositing the semiconductor material to a thickness in the range of about 10 nanometers (nm) to 100 nm.

7. The method of claim 1 wherein forming the metal top and bottom electrodes includes forming each electrode with a thickness in the range of about 30 to 200 nm.

8. The method of claim 1 further comprising:
doping the semiconductor layer with a dopant selected from the group consisting of n-type and p-type dopants.

9. A method for forming a resistance memory device with a metal/semiconductor/metal (MSM) back-to-back Schottky diode, the method comprising:
forming a memory resistor bottom electrode;
forming a memory resistor material overlying the memory resistor bottom electrode;
forming a MSM metal bottom electrode overlying the memory resistor material, having a first work function;
forming a MSM semiconductor layer overlying the metal bottom electrode, having a second work function, less than the first work function; and,
forming a MSM metal top electrode overlying the semiconductor layer, having a third work function, greater than the second work function.

10. The method of claim 9 further comprising:
forming a memory resistor top electrode interposed between the memory resistor material and the MSM metal bottom electrode.

11. The method of claim 9 wherein forming the memory resistor material overlying the memory resistor bottom electrode includes forming the memory resistor from a material selected from the group comprising Pr_{0.3}Ca_{0.7}MnO₃ (PCMO), colossal magnetoresistive (CMR) film, transition metal oxides, Mott insulators, high-temperature super conductor (HTSC), and perovskite materials.

12. A metal/semiconductor/metal (MSM) back-to-back Schottky diode, the MSM diode comprising:
a substrate;
a metal bottom electrode overlying the substrate, having a first work function;
a semiconductor layer overlying the metal bottom electrode, having a second work function, less than the first work function; and,
a metal top electrode overlying the semiconductor layer, having a third work function, greater than the second work function.

13. The MSM diode of claim 12 wherein the metal top electrode and metal bottom electrode are the same material, having identical work functions.

14. The MSM diode of claim 12 wherein the metal top electrode and metal bottom electrode are materials selected from the group consisting of Pt, Au, Ag, TiN, Ta, Ru, and TaN.

15. The MSM diode of claim 12 wherein the semiconductor layer is a material selected from the group consisting of amorphous silicon (a:Si), polycrystalline Si, InOx, and ZnO.

16. The MSM diode of claim 12 wherein the semiconductor layer has a thickness in the range of about 10 nanometers (nm) to 100 nm.

17. The MSM diode of claim 12 wherein the metal top and bottom electrodes each have a thickness in the range of about 30 to 200 nm.

18. The MSM diode of claim 12 wherein the semiconductor layer includes a dopant selected from the group consisting of n-type and p-type dopants.

19. A resistance memory device with a metal/semiconductor/metal (MSM) back-to-back Schottky diode, the device comprising:
a memory resistor bottom electrode;
a memory resistor material overlying the memory resistor bottom electrode;
a MSM metal bottom electrode overlying the memory resistor material, having a first work function;
a MSM semiconductor layer overlying the metal bottom electrode, having a second work function, less than the first work function; and,
a MSM metal top electrode overlying the semiconductor layer, having a third work function, greater than the second work function.

20. The device of claim 19 further comprising:
a memory resistor top electrode interposed between the memory resistor material and the MSM metal bottom electrode.

21. The device of claim 19 wherein the memory resistor material overlying the memory resistor bottom electrode is a material selected from the group comprising Pr_{0.3}Ca_{0.7}MnO₃ (PCMO), colossal magnetoresistive (CMR) film, transition metal oxides, Mott insulators, high-temperature super conductor (HTSC), and perovskite materials.
